(19) United States
(12) Patent Application Publication
(10) Pub. No.: US 2008/0112575 A1
(43) Pub. Date: May 15, 2008

(54) Volume control device for vehicle audio system

(75) Inventor: Norihiro Isobe, Tokai-city (JP)

Correspondence Address: HARNESS, DICKEY & PIERCE, P.L.C., P.O. BOX 828, BLOOMFIELD HILLS, MI, 48303, US

(73) Assignee: DENSO Corporation

(21) Appl. No.: 11/982,768

(22) Filed: Nov. 5, 2007

(30) Foreign Application Priority Data
Nov. 15, 2006 (JP) 2006-309164

(51) Int. Cl. H03G 3/00; H04B 1/00

(52) U.S. Cl. 381/104; 381/86

(57) ABSTRACT

A volume control device for controlling a volume of an audio system includes a volume control unit and a volume resetting control unit. The volume control unit executes a volume control when a reception of an incoming call by a telephone is detected while an audio device of the audio system is in use. Here, the volume control unit changes the volume of the audio device from a present level to a first level that is lower than the present level. The volume resetting control unit executes a volume resetting control when an end of a call by the telephone is detected. Here, the volume resetting control unit changes the volume from the first level to a second level if the present level exceeds a reference value.

### CROSS REFERENCE TO RELATED APPLICATION

This application is based on and incorporates herein by reference Japanese Patent Application No. 2006-309164 filed on Nov. 15, 2006.

### BACKGROUND OF THE INVENTION

1. Field of the Invention

The present invention relates to a device that controls a volume of a vehicle audio system. Typically, the vehicle audio system is communicated with a telephone mounted on a vehicle, and provides a handsfree telephone call function by using a speaker mounted in the vehicle.

2. Description of Related Art

A vehicle audio system and a navigation system include a system that provides a handsfree telephone call function using a mobile phone and a vehicle telephone. Also, in the above structure, when the mobile phone receives an incoming call while a car radio or a car stereo is in use, the volume of audio device is temporarily turned down in order to start the handsfree telephone call. Also, the above system is structured such that the turned-down volume is returned to its previous state when the end of the telephone call is detected. (see JP-A-2006-121270, FIG. 5).

However, for example, while the vehicle drives in a highway, or in a noisy place, the volume of the audio device may be often set at a volume higher than usual. Under the above situation, the handsfree telephone call may be started, and then, the volume may be returned to the previous volume when the telephone call has been ended. In this case, when the vehicle has moved to a relatively quiet place, such as a parking area, the returned volume may be so large that an occupant of the vehicle may be surprised. Also, this may disturb others around.

### SUMMARY OF THE INVENTION

The present invention is made in view of the above disadvantages. Thus, it is an objective of the present invention to address at least one of the above disadvantages.

To achieve the objective of the present invention, there is provided a volume control device for controlling a volume of an audio system, wherein the audio system is in communication with a telephone in a vehicle to provide a handsfree telephone call function using a speaker mounted in the vehicle, the volume control device including a volume control unit and a volume resetting control unit. The volume control unit is configured to execute a volume control when a reception of an incoming call by the telephone is detected while an audio device of the audio system is in use. Here, the volume control unit executes the volume control by changing the volume of the audio device from a present level to a first level that is lower than the present level. The volume resetting control unit is configured to execute a volume resetting control when an end of a call by the telephone is detected. Here, the volume resetting control unit executes the volume resetting control by changing the volume of the audio device from the first level to a second level if the present level exceeds a reference value, the second level being lower than the present level and higher than the first level.

### BRIEF DESCRIPTION OF THE DRAWINGS

The invention, together with additional objectives, features and advantages thereof, will be best understood from the following description, the appended claims and the accompanying drawings in which:

FIG. 1 is a function block diagram showing a structure of a vehicle audio system according to a first embodiment of the present invention;

FIG. 2 is a flow chart showing controls executed mainly by a control portion while an audio device is in use;

FIG. 3A is a timing chart showing a case where a volume resetting control is executed;

FIG. 3B is a timing chart showing another case where the volume resetting control is not executed;

FIG. 4 is a diagram equivalent to FIG. 1 according to a second embodiment of the present invention;

FIG. 5 is a diagram equivalent to FIG. 2 according to the second embodiment;

FIG. 6 is a diagram equivalent to FIG. 1 according to a third embodiment of the present invention; and

FIG. 7 is a diagram equivalent to FIG. 1 according to a fourth embodiment the present invention.

### DETAILED DESCRIPTION OF PREFERRED EMBODIMENTS

### First Embodiment

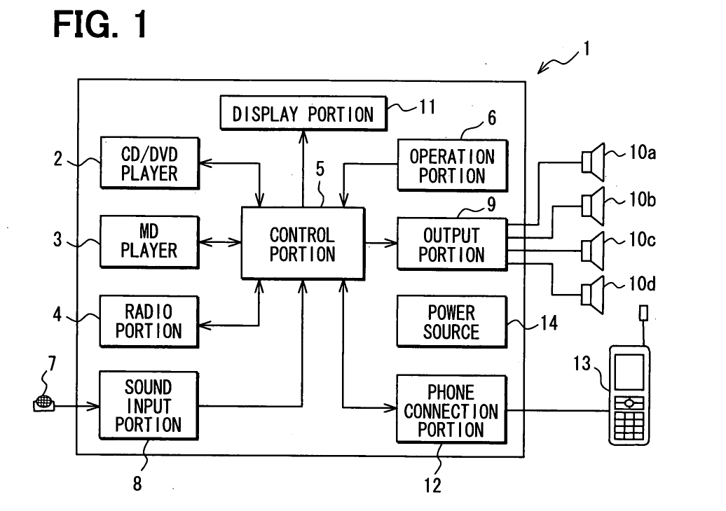

The first embodiment of the present invention is described below referring to FIG. 1 to FIG. 3. In a vehicle audio system 1 of FIG. 1, a control portion 5 (volume control device) controls each of audio devices, such as a CD/DVD player 2, an MD player 3, a radio portion 4, in accordance with an operation by a user (i.e., an occupant of a vehicle). The control portion 5 includes a microcomputer, and controls a control target for various controls. Here, the control target is designated by the user through an operation of keys arranged in an operation portion 6. Also, the user can inputs sound into a microphone 7 to give a command to the control portion 5 such that the inputted sound is recognized and processed in a sound input portion 8 to be outputted to the control portion 5.

The CD/DVD player 2 plays a CD (Compact Disk) or a DVD (Digital Versatile Disk) placed by the user, and the MD player 3 plays an MD (Mini Disk) similarly placed by the user. Also, the radio portion 4 receives radio waves from AM and FM stations in response to the selection by the user. Sound signals outputted by the above audio devices are outputted through, typically, speakers 10a to 10d mounted at four positions in the vehicle cabin via the control portion 5 and an output portion 9. The output portion 9 includes an amplifier that drives the speakers 10, and the amplification factor (e.g., gain) of the amplifier is set by the control portion 5.

A display portion 11 includes, for example, a liquid crystal panel. The display portion 11 typically displays a control state of each audio device in accordance with a display control signal given by the control portion 5, and also displays play data of each medium, such as a CD, a DVD, an MD. Also, the control portion 5 is configured to communicate with a mobile phone 13 via a phone connection portion 12. Here, the mobile phone 13 is brought into the vehicle cabin (vehicle). The phone connection portion 12 may have a wired interface or a wireless interface. Typically, the wired interface includes a USB (Universal Serial Bus), and the wireless interface includes a Bluetooth, which is a registered trademark.

Due to the above structure, the control portion 5 can detect a reception of an incoming call of the mobile phone 13, and also can detect the telephone call of the mobile phone 13. Also, when the control portion 5 receives a reception sound received through the mobile phone 13, the control portion 5 outputs the sound through the speakers 10. Also, the control portion 5 transmits a transmission sound inputted through the microphone 7 to the mobile phone 13 such that the handsfree telephone call is realized. It is noted that a power source 14 is configured to be supplied with power from a battery power source (not shown) of the vehicle to generate an operation power for the audio system 1. Thus, the power source 14 supplies the power to each component.

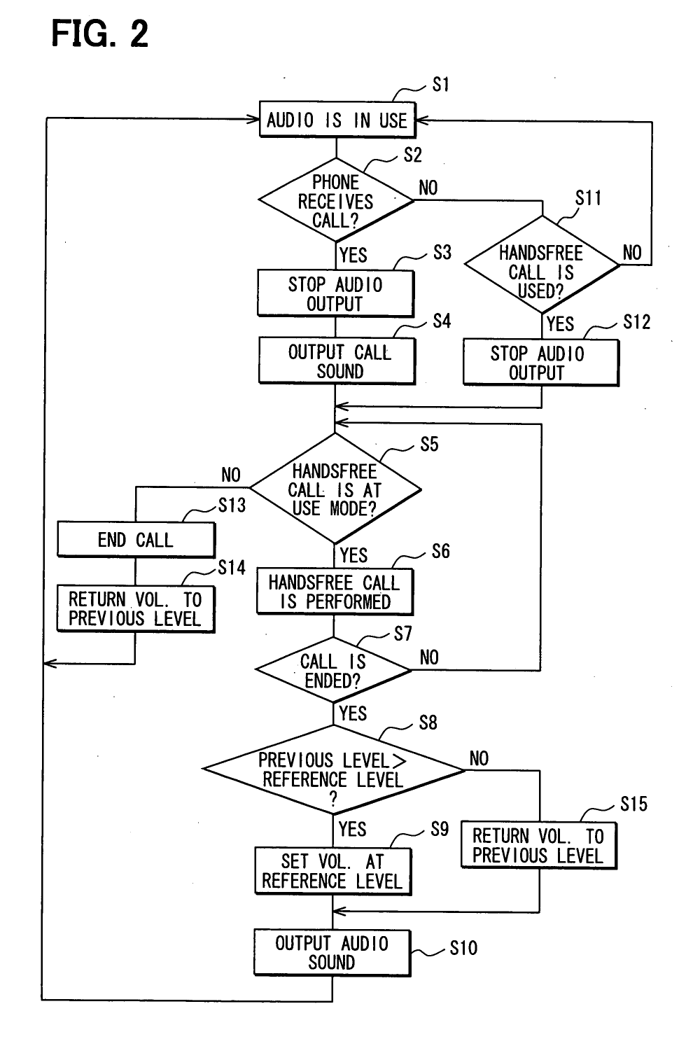

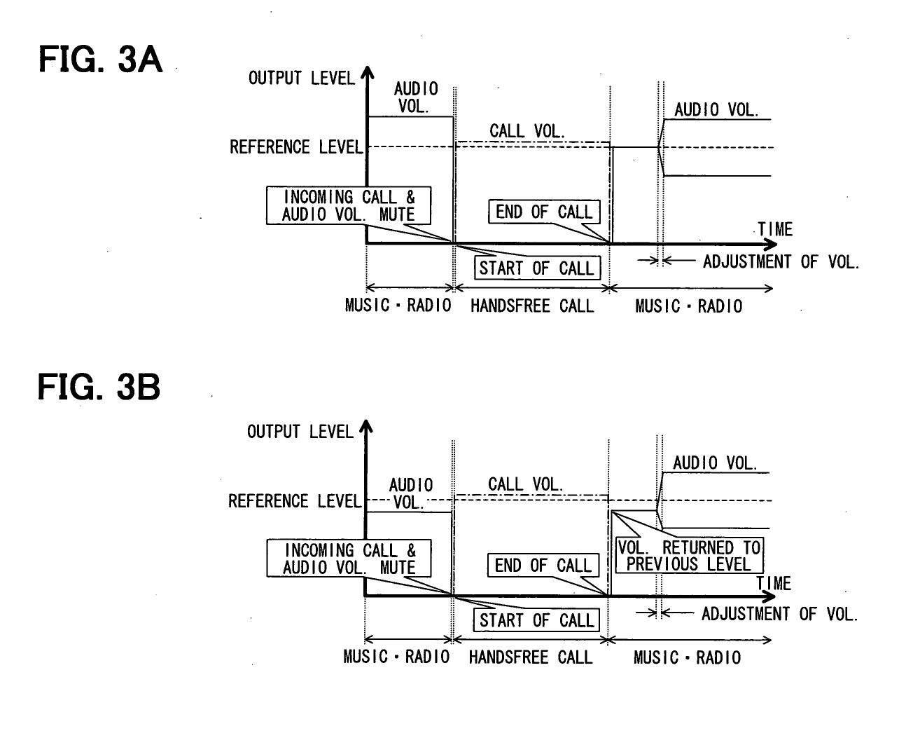

Next, an operation of the present embodiment is described referring to FIG. 2 and FIGS. 3A to 3D. FIG. 2 is a flow chart of a control executed mainly by the control portion 5 while the user uses one of the audio devices. When the user operates one of the CD/DVD player 2, the MD player 3, and the radio portion 4, and when its play back sound is outputted through the speakers 10 at step S1, the control portion 5 monitors at step S2 whether the mobile phone 13 receives the incoming call. When the mobile phone 13 does not receive the incoming call (NO at step S2), also when the handsfree telephone call is not made at this point (NO at step S11), control returns to step S1 to repeat playing the audio device.

In contrast, when the mobile phone 13 receives the incoming call (YES at step S2), the control portion 5 turns down the volume of the audio device that is played at this point to zero at step S3. This operation corresponds to a volume control to stop an output of the sound of the audio device, and therefore, the volume of the audio device is change from a present level to a first level (zero) that is lower than the present level. It is noted that at this time, a volume level of the audio device is stored. Then, the control portion 5 outputs an incoming call ring through the speakers 10 in order to alarm the user of the reception of the incoming call by the mobile phone 13 (step S4).

Next, the control portion 5 determines at step S5 whether the user has, in advance, set a use mode for the handsfree telephone call function, or determines whether the user is going to use the handsfree telephone call function based on an operation input at this point. When the handsfree telephone call function is set at the use mode (YES at step S5), the handsfree telephone call function is executed at step S6. In other words, as described above, the reception sound received by the mobile phone 13 is outputted through the speakers 10, and at the same time, the transmission sound data inputted to the microphone 7 is transmitted through the mobile phone 13. Then, step S6 is repeated until the telephone call is finished. Also, if the user does not choose to user the handsfree telephone call function (NO at step S5), the telephone call of the mobile phone 13 is stopped at this point (step S13). Then, at step S14, the volume of the audio device is returned to the previous volume before the volume control at step S3, and control returns to step S1. That is, the volume of the audio device is changed from the first level to the above present level that corresponds to a level of the previous volume before the volume control.

Also, when the user dials the mobile phone 13 for the handsfree telephone call, the control portion 5 determines NO at the step S2, and YES at step S11. Thus, the control portion 5 executes the volume control at step S12 similar to step S3, and continues with step S6.

When the handsfree telephone call is ended (YES at step S7), the control portion 5 determines at step S8 whether the previous volume level (the present level) before the volume control exceeds a reference value. Here, the reference value is typically set equal to or less than a volume of a call that is set for the handsfree telephone call. Here, if a disturbing value is defined as a level of the volume of the audio device for disturbing the occupant when the sound output of the audio device is restarted, the disturbing value may be appropriately assumed to be a level that exceeds the volume of the call (talk) during the handsfree telephone call.

Then, when the previous volume level before the volume control exceeds the reference value (YES at step S8), it is assumed that the occupant of the vehicle may be surprised or this may disturb others around in a case where the sound output is restarted at the previous volume level. Therefore, after the volume of the audio device has been set equal to the reference value (i.e., reference level) at step S9, the sound is outputted at the reset volume through the speakers 10 at step S10. This operation corresponds to a volume resetting control. Here, FIG. 3A shows a timing chart showing a change of the volume when operations at steps S8, S9, S10 are executed.

In contrast, when the previous volume level before the volume control is equal to or less than the reference value (NO at step S8), the volume of the audio device is returned to the previous volume level before the volume control at step S15, and control continues with step S10. In this case, even when the volume level is returned to the previous volume level, the occupant of the vehicle is not surprised and this does not disturb others around. FIG. 3B is a timing chart showing a change of the volume in a case where the operations at steps S8, S15, S10 are executed. It is noted that when the sound output of the audio device is restarted at step S10, the volume may be gradually increased (fade-in) in accordance with a setting by the user.

As above, according to the present embodiment, in the audio system 1, when the control portion 5 detects that the mobile phone 13 in the vehicle cabin receives the incoming call while the audio device is operated, the volume control for stopping the sound output of the audio device is operated. Also, in a case where the control portion 5 detects that the handsfree telephone call by the mobile phone 13 has ended, if the previous volume before the volume control exceeds the reference value, the volume resetting control is executed for making the volume of the audio device at a level lower than. That is, when the control portion 5 detects that the handsfree telephone call by the mobile phone 13 has ended and also when the present level) the exceeds the reference value, the volume resetting control is executed by changing the volume of the audio device from the first level (zero) to a second level. Here, for example, the second level is lower than the present level and higher than the first level. For example, the second level corresponds to the reference value as shown in FIG. 3A.

Therefore, even when the vehicle moves or time elapses during the telephone call such that the volume level of sound from surrounding environments becomes lower, the occupant of the vehicle is limited from feeling that the volume of the audio device is comparatively large. As a result, the occupant of the vehicle is limited from being surprised, or disturbance of others around can be limited. Also, because the reference value is set equal to or lower than the volume of the call that is set at a time of the handsfree telephone call, the volume of the audio device is changed to be equal to or less than the volume for the handsfree telephone call, when the sound output of the audio device is restarted. Therefore, the volume of the audio device when the can be appropriately set.

### Second Embodiment

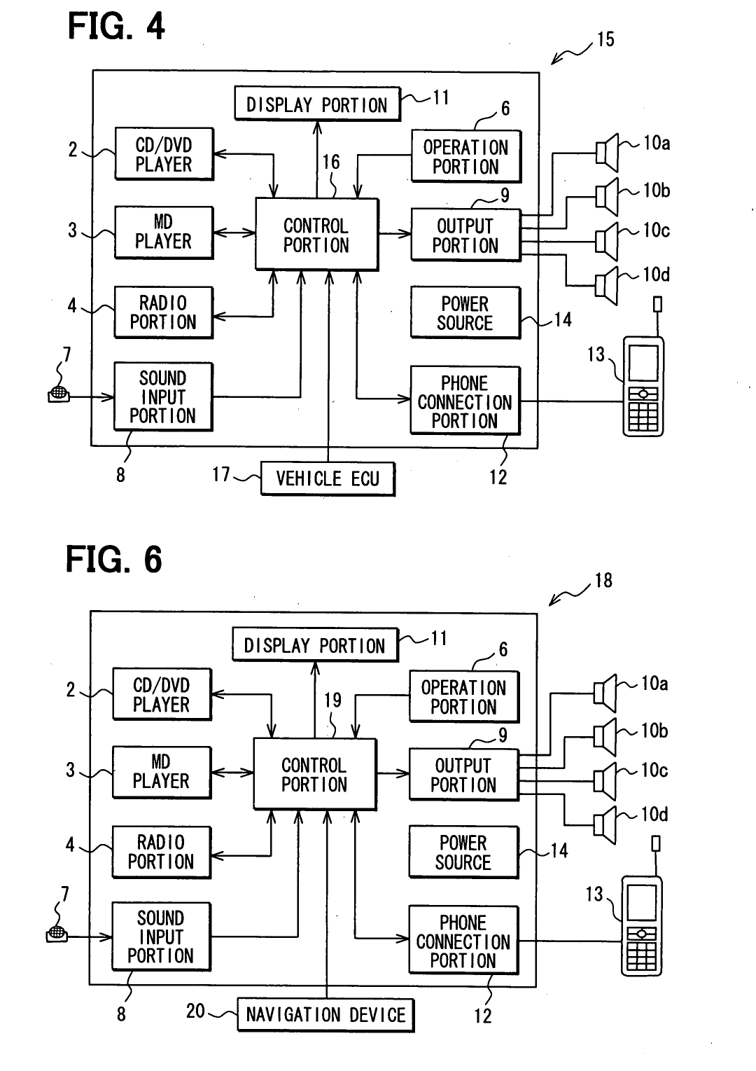

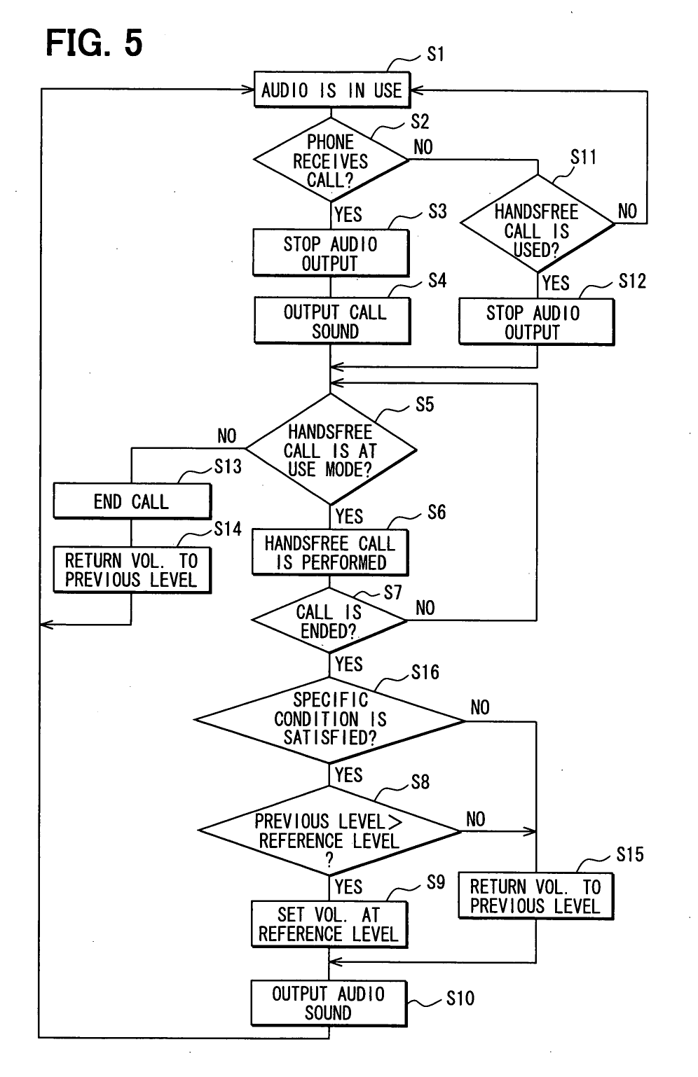

The second embodiment of the present invention is described referring to FIG. 4 and FIG. 5. Similar components of the present embodiment similar to those of the first embodiment are indicated by the same numerals, and explanation thereof is omitted. Different points from the first embodiment are described. A vehicle audio system 15 of the second embodiment includes a control portion 16 (volume control device) that replaces the control portion 5 of the first embodiment. The control portion 16 is communicated with an ECU 17 (Electronic Control Unit) mounted on the vehicle via, for example, an in-vehicle LAN. Then, the control portion 16 is configured to retrieve information (drive information) about a drive operation of the vehicle from the ECU 17.

FIG. 5 is a diagram equivalent to FIG. 2 of the first embodiment. When the control portion 16 determines YES at step S7, control continues with step S16 to retrieve the drive information of the vehicle from the ECU 17 (drive information retrieval unit). Then, the control portion 16 determines whether a predetermined specific condition (i.e., an effective condition for making the volume resetting control effective) is satisfied or not based on the drive information. When the specific condition is satisfied (YES at step S16, control continues with step S to execute the volume resetting control. When the specific condition is not satisfied (NO at step S16), control continues with step S15.

Here, the above specific condition is used for determining whether the execution of the volume resetting control is appropriate or not, and may include the followings.

(1) When it is determined that the vehicle runs (speed>0) by referring running speed information, “the condition is satisfied”. Also, when a shift position of the vehicle corresponds to a position other than “Parking”, it is determined that the vehicle runs, and thereby “the condition is satisfied.” In this way, when the vehicle runs, the surrounding conditions (e.g., background noise level) change. Thus, the volume resetting control is executed.

(2) When it is determined that a switch for a headlight or a side lamp is on by referring ON/OFF information of the switch for the headlight or the side lamp, “the condition is satisfied”. In other words, when the headlight or the side lamp is on, it is determined that hours (time) is assumed to correspond to a night time. Thus, the volume resetting control is executed because a level of the environmental sound is usually low at the night time.

It is noted that alternatively, when at least one of the above conditions (1), (2) is satisfied, the condition may be satisfied to make the volume resetting control effective.

As above, according to the second embodiment, the control portion 16 makes the volume resetting control when the drive information retrieved from the ECU 17 on the vehicle satisfies the specific condition. In other words, when the drive information is referred, the state of the vehicle can be estimated. Thus, when the retrieved information satisfies the specific condition for appropriately executing the volume resetting control, the volume resetting control can be appropriately executed. Specifically, the drive information indicates that the vehicle is running, or that the headlight or the side lamp is on, the volume resetting control is made effective. As a result, if the vehicle moves or if it is the night time, the volume resetting control is appropriately executed.

### Third Embodiment

The third embodiment of the present invention is described referring to FIG. 6. Similar components of the present embodiment similar to those of the above embodiments are indicated by the same numerals, and explanation thereof is omitted. Different points from the second embodiment are described. A vehicle audio system 18 of the third embodiment includes a control portion 19 (volume control device) that replaces the control portion 16. The control portion 19 is configured to be connected with a vehicle navigation device 20 (position information retrieval unit) for electrical communication. Also, the control portion 19 is configured to retrieve a position information of the vehicle from a navigation device 20. Also in this case, a route guidance sound and the like from the navigation device 20 is outputted through the speakers 10 via the control portion 19.

Then, at step S16 of a flow chart shown in FIG. 5, “specific condition” includes the followings, for example.

(1) When a position of the vehicle is located in a residential area, “the condition is satisfied”.

(2) When the position of the vehicle is located in a parking area, “the condition is satisfied”.

In other words, because the residential area and the parking area are comparatively quiet environments, the volume resetting control can be effectively performed. It is noted that alternatively, when at least one of the above conditions (1), (2) is satisfied, the condition may also be satisfied to make the volume resetting control effective.

As above, according to the third embodiment, when the position of the vehicle retrieved from the navigation device 20 corresponds to a position of or near a specific place (i.e., the residential area, the parking are), the control portion 19 makes the volume resetting control effective. That is, when the vehicle comes close to or arrives at the specific place, the volume resetting control is made effective. Therefore, when the vehicle is located at a place that is generally assumed to be quiet, the volume control of the embodiment of the present invention can be appropriately executed.

### Fourth Embodiment

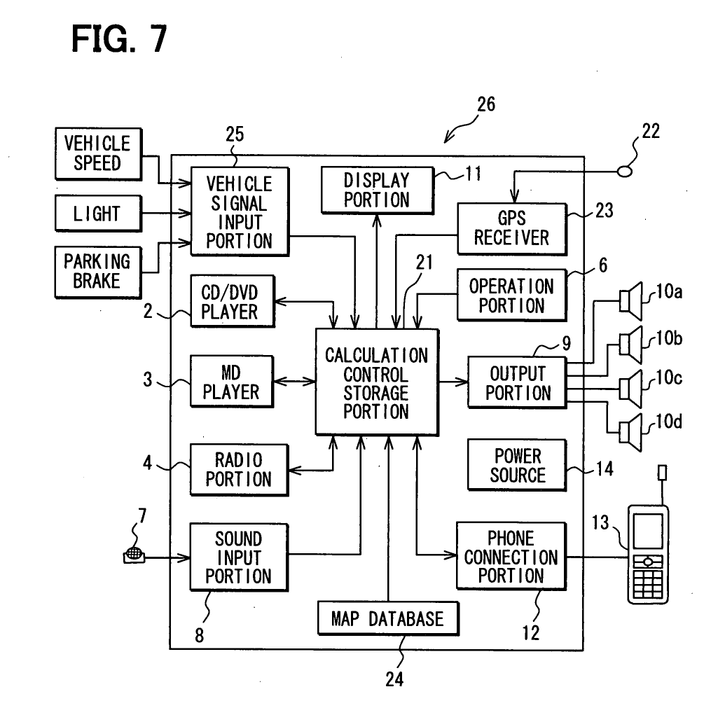

The fourth embodiment of the present invention is described referring to FIG. 7. Similar components of the present embodiment similar to those of the above embodiments are indicated by the same numerals, and explanation thereof is omitted. In the fourth embodiment, a vehicle navigation device 20, which is a part of the vehicle the audio system 18 in the third embodiment, is integrated as a system. In other words, the control portion 19 of the third embodiment is replaced with a calculation portion/control portion/storage portion 21 (volume control device). Typically, the calculation portion/control portion/storage portion 21 provides a vehicle navigation function, and is referred as a control portion 21.

The control portion 21 retrieves the position information of the vehicle based on a GPS signal received via a GPS antenna 22 and a GPS receiver 23 (position information retrieval unit). Then, the control portion 21 retrieves map data that corresponds to the position of the vehicle from a map database 24 (position information retrieval unit) to display the map data in the display portion 11. Also, the control portion 21 retrieves a vehicle speed signal, a parking signal, a lighting signal of a light (headlight or side lamp), and the like from the vehicle via the vehicle signal input portion 25. The above components constitute an audio system 26, and achieve the similar advantages achieved by the first to third embodiments.

Also, when the vehicle arrives at a position of or near a destination designated by a driver (user) due to the navigation function executed by the control portion 21, it is determined that the condition is satisfied to be able to execute the volume resetting control. In other words, when the vehicle comes close to or arrives at the destination, it is assumed that the occupant may get off the vehicle in the near future. Thus, the occupant has small probability to continue listening to the audio device, and the execution of the volume resetting control is appropriate.

As above, according to the fourth embodiment, because the audio system 26 is integrally configured to function as a navigation device such that the control portion 21 controls the navigation function, the whole system is reduced in size. Also, when the vehicle comes close to or arrives at the designated destination (set destination), the volume resetting control can be appropriately executed.

### Fifth Embodiment

Also, a system of the fifth embodiment includes a vehicle speed sensor that detects the speed of the vehicle. Then, a vehicle speed (first vehicle speed) during the handsfree telephone call is compared with another vehicle speed (second vehicle speed) after ending of the handsfree telephone call. When the second vehicle speed is lower than the first vehicle speed, the specific condition of step S16 shown in FIG. 5 is determined to be satisfied. Thus, the volume resetting control is made effective.

While the vehicle is running at a high speed, a running sound, an engine sound, and the like become larger. Consequently, the volume of the audio device is often raised while the vehicle runs at the high speed. At this time, the incoming call may be received and the handsfree telephone call may be performed. In a case, where the vehicle starts running at a lower speed during the telephone call or after the end of the telephone call, if the volume of the audio device returns to the previous volume, the user may be disadvantageously surprised by the large volume, or this may cause noises for surroundings conventionally.

However, in the present embodiment, the above disadvantages can be solved.

The present invention is not limited to the embodiments described in the above description or in the drawings, and the followings modifications are applicable.

“The volume control” is not limited to completely stopping of the sound output. That is, the volume control does not necessarily completely stop the output of the sound. However, the volume control may alternatively decrease the volume level to a level that does not disturb the telephone call.

For example, the modification may be provided with a real time clock IC as a timer that measures a time. Thus, by referring the present time, the volume resetting control may be alternatively made effective during hours corresponding to the night time (e.g., 22:00 to 5:00). In this case, the similar advantages similar to the second embodiment can be also achieved.

The reference value may be changed in accordance with the effective condition for making the volume resetting control effective. In other words, the appropriate volume of the audio device appropriate for the volume resetting control depends on the condition of the vehicle at the time. Therefore, if the volume reference value is changed in accordance with the effective condition, the volume resetting control can be appropriately executed in accordance with the condition of the vehicle.

The specific conditions for the position of the vehicle in the third embodiment are not limited to the examples above. However, other places that are assumed to be under a comparatively quiet environment can be selectable for the specific condition as necessary.

For example, in the structure in the third embodiment, the drive information from the vehicle may be alternatively retrieved by the navigation device 20 such that the similar control similar to the second embodiment is executed. Also, in the case of the third embodiment, the reference value may alternatively be set equal to or less than the volume of the route guidance by the navigation device 20.

The telephone is not limited to the mobile phone 13. However, a vehicle telephone fixed to the vehicle cabin can be alternatively employed.

The audio device may be another alternative device in accordance with each design as necessary. For example, the audio device may be a digital audio player, such as a hard disk audio player using a hard disk drive for storing music data, or a flash memory audio player using a nonvolatile memory for storing music data. Also, the audio device may be a portable audio player that is connected to the audio system.

Additional advantages and modifications will readily occur to those skilled in the art. The invention in its broader terms is therefore not limited to the specific details, representative apparatus, and illustrative examples shown and described.

What is claimed is:

1. A volume control device for controlling a volume of an audio system, wherein the audio system is in communication with a telephone in a vehicle to provide a handsfree telephone call function using a speaker mounted in the vehicle, the volume control device comprising:
a volume control unit configured to execute a volume control when a reception of an incoming call by the telephone is detected while an audio device of the audio system is in use, the volume control unit executing the volume control by changing the volume of the audio device from a present level to a first level that is lower than the present level; and
a volume resetting control unit configured to execute a volume resetting control when an end of a call by the telephone is detected, the volume resetting control unit executing the volume resetting control by changing the volume of the audio device from the first level to a second level if the present level exceeds a reference value, the second level being lower than the present level and higher than the first level.

2. The volume control device according to claim 1, further comprising:
a timer that measures a time, wherein:
the volume resetting control is made effective when the time measured by the timer corresponds to a night time.

3. The volume control device according to claim 1, further comprising:
a drive information retrieval unit configured to retrieve drive information about an drive operation from the vehicle, wherein:
the volume resetting control is made effective when the drive information satisfies a specific condition for appropriately executing the volume resetting control.

4. The volume control device according to claim 3, wherein the volume resetting control is made effective when the drive information indicates that the vehicle is running.

5. The volume control device according to claim 3, wherein the volume resetting control is made effective when the drive information indicates one of a headlight and a side lamp is on.

6. The volume control device according to claim 1, further comprising:
a position information retrieval unit configured to retrieve position information from a navigation device mounted on the vehicle, the position information indicating a position of the vehicle, wherein the volume resetting control is made effective when the position of the vehicle corresponds to a specific position.

7. The volume control device according to claim 6, wherein the volume resetting control is made effective when the position of the vehicle corresponds to a residential area.

8. The volume control device according to claim 6, wherein the volume resetting control is made effective when the position of the vehicle corresponds to a parking area.

9. The volume control device according to claim 6, wherein the volume resetting control is made effective when the vehicle comes close to or arrives at a destination set by the navigation device.

10. The volume control device according to claim 6, wherein the vehicle audio system is provided integrally with the navigation device.

11. The volume control device according to claim 2, wherein the reference value is changed in accordance with an effective condition for making the volume resetting control effective.

12. The volume control device according to claim 1, wherein the reference value is set equal to or lower than a volume of the call that is set during a handsfree telephone call.

13. The volume control device according to claim 1, wherein the first level of the volume of the audio device corresponds to zero to stop an output of a sound of the audio device.

14. The volume control device according to claim 1, further comprising:
a vehicle speed sensor that is configured to sense a first speed of the vehicle during the call by the handsfree telephone call function, the vehicle speed sensor sensing a second speed of the vehicle after an end of the call by the handsfree telephone call function, wherein:
the volume resetting control is made effective when the second speed is lower than the first speed.
